(19) United States
(12) Patent Application Publication
(10) Pub. No.: US 2016/0295728 A1
(43) Pub. Date: Oct. 6, 2016

(54) DIRECTLY SERVICEABLE HARD DRIVE BAY IN MODULAR SERVER CHASSIS ASSEMBLY

(71) Applicant: DELL PRODUCTS, L.P., Round Rock, TX (US)

(72) Inventors: DANIEL ALVARADO, PFLUGERVILLE, TX (US); EDMOND I. BAILEY, CEDAR PARK, TX (US); WALTER R. CARVER, ROUND ROCK, TX (US)

(21) Appl. No.: 14/673,032

(22) Filed: Mar. 30, 2015

(51) Int. Cl. H05K 5/03; H05K 5/02; G06F 1/16

(52) U.S. Cl. CPC H05K 5/03; G06F 1/16; H05K 5/0226; H05K 5/0204

(57) ABSTRACT

An Information Handling System (IHS) includes a chassis configured with infrastructure components arranged for housing one or more compute components. The chassis includes a bottom segment having a base wall to receive the one or more compute components. One or more connecting cabling interconnects the compute components to assemble a fully functional IHS. A cover is fixedly engaged to the bottom segment to form a casing enclosing inserted IHS components. The cover has at least one access panel that can be moved from a closed position to an open position to expose one or more top loaded slots and enable insertion and/or removal of the respective compute component, after assembly of the chassis.

### BACKGROUND

1. Technical Field

This disclosure generally relates to information handling systems (IHS), and more particular to a modularly-assembled IHS and a chassis cover supporting direct serviceability of compute components within the modularly-assembled IHS.

2. Description of the Related Art

As the value and use of information continue to increase, individuals and businesses seek additional ways to process and store information. One option available to users is information handling systems (IHSs). An IHS generally processes, compiles, stores, and/or communicates information or data for business, personal, or other purposes, thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

IHSes typically rely largely upon optical or hard disk storage drives for nonvolatile storage of data and executable instructions. As compared to solid state compute components, storage drives tend to require replacement during the service life of an IHS. Storage drives are typically fastened into an IHS chassis. Servicing the storage drive generally requires removing the entire IHS from an IHS rack (when the IHS is inserted into an IHS rack), removing fasteners that attach a cover to the chassis, and unscrewing fasteners within the chassis that retain the storage drive within a bay of the chassis. The duration of such servicing can disrupt availability of the IHS and create a maintenance burden in servicing both the individual or stand-alone IHS and a data center of rack-based IHSes.

### BRIEF SUMMARY

The illustrative embodiments of the present disclosure provide a chassis assembly of an information handling system (IHS) that includes a bottom segment or chassis having a base to receive one or more compute components. The chassis assembly also includes a chassis cover having a fixed portion that is fixably engaged to the bottom segment to form a casing enclosing inserted IHS components and a moveable portion. The moveable portion of the cover includes and/or provides at least one access panel that can be moved from a closed position to an open position relative to the chassis assembly to expose one or more top loaded slots inside the chassis assembly. When placed in the open position, the moveable portion of the cover enables insertion and/or removal of a respective compute component into or out of one of the top loaded slots, after affixing the chassis cover to the chassis to provide the completed chassis assembly.

According to at least one aspect of the present disclosure, an IHS includes a chassis configured with infrastructure components arranged for housing one or more compute components. The chassis includes a bottom segment having a base wall to receive the one or more compute components. One or more connecting cabling interconnects the compute components to assemble a fully functional IHS. A cover is fixedly engaged to the bottom segment to form a casing enclosing inserted IHS components. The cover has at least one access panel that can be moved from a closed position to an open position to expose one or more top loaded slots within the chassis and enable insertion and/or removal of the respective compute component. Insertion and/or removal of the respective compute component can thus be completed after assembly of the chassis without having to remove the entire cover.

According to at least one aspect of the present disclosure, a method is provided of manufacturing a chassis of an IHS. In one or more embodiments, the method includes manufacturing a bottom segment with a base wall configured to receive one or more compute components. The method includes forming a cover that is fixedly engageable to the bottom segment to enclose inserted IHS components. The method includes forming the cover to include at least one access panel that can be moved from a closed position to an open position to expose one or more top loaded slots and enable insertion and/or removal of the respective compute component, after assembly of the chassis.

The above presents a general summary of several aspects of the disclosure in order to provide a basic understanding of at least some aspects of the disclosure. The above summary contains simplifications, generalizations and omissions of detail and is not intended as a comprehensive description of the claimed subject matter but, rather, is intended to provide a brief overview of some of the functionality associated therewith. The summary is not intended to delineate the scope of the claims, and the summary merely presents some concepts of the disclosure in a general form as a prelude to the more detailed description that follows. Other systems, methods, functionality, features and advantages of the claimed subject matter will be or will become apparent to one with skill in the art upon examination of the following figures and detailed written description.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 illustrates a perspective view of a disassembled Information Handling System (IHS) having a cover that facilitates servicing of compute components housed in a chassis, according to one or more embodiments;

FIG. 2 illustrates a perspective side view of an example IHS with a planar cover in a closed position, according to one or more embodiment;

FIG. 3 illustrates a top perspective view of the chassis of FIG. 1 housing compute components, including storage drives that can require servicing, according to one or more embodiments;

FIG. 4 illustrates a perspective side view of the example IHS of FIG. 3 with an access panel of the planar cover open, according to one or more embodiments;

FIG. 5A illustrates a perspective side view of a storage drive being serviced through the open access panel of FIG. 4, according to one or more embodiments;

FIG. 5B illustrates a detail perspective side view of the storage drive being serviced through the open access panel of FIG. 5A, according to one or more embodiments;

FIG. 6 illustrates a flow diagram of a method of manufacturing a chassis of an IHS having a cover with an access panel, according to one or more embodiments; and

FIG. 7 illustrates a block diagram of a manufacturing system for forming a chassis cover of an IHS with an access panel, according to one or more embodiments.

### DETAILED DESCRIPTION

According to one or more embodiments, an Information Handling System (IHS) includes a chassis configured with infrastructure components arranged for housing one or more compute components. The chassis includes a bottom segment having a base wall to receive the one or more compute components. One or more connecting cabling interconnects the compute components to assemble a fully functional IHS. A cover is fixedly engaged to the bottom segment to form a casing enclosing inserted IHS components. The cover has at least one access panel that can be moved from a closed position to an open position to expose one or more top loaded slots and enable insertion and/or removal of the respective compute component, after assembly of the chassis.

In an example embodiment, IHS provides a storage drive bay at the back end of a server chassis that is at least one of (a) slideably inserted into a socket or bay of the chassis to allow for easy access for servicing; and (b) accessible via a flap in the chassis cover, that can be flipped up to expose the hard drives.

In the following detailed description of exemplary embodiments of the disclosure, specific exemplary embodiments in which the disclosure may be practiced are described in sufficient detail to enable those skilled in the art to practice the disclosed embodiments. For example, specific details such as specific method orders, structures, elements, and connections have been presented herein. However, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure. The following detailed description is, therefore, not to be taken in a limiting sense, and the scope of the present disclosure is defined by the appended claims and equivalents thereof.

References within the specification to “one embodiment,” “an embodiment,” “embodiments”, or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

It is understood that the use of specific component, device and/or parameter names and/or corresponding acronyms thereof, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

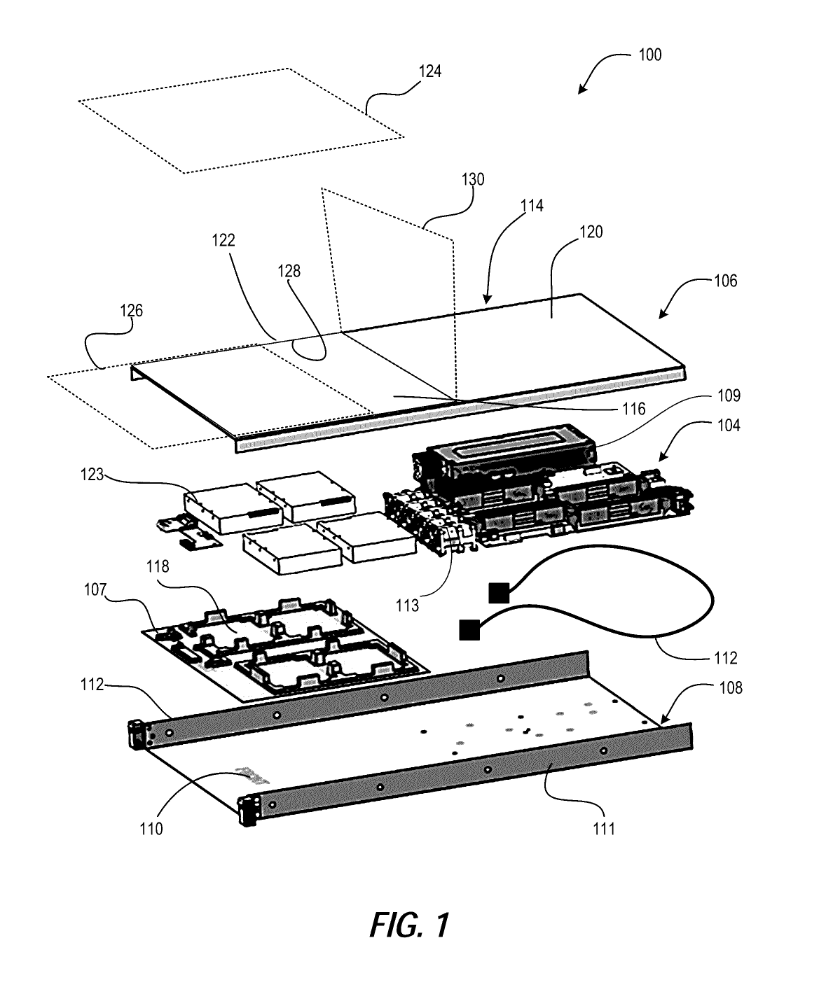

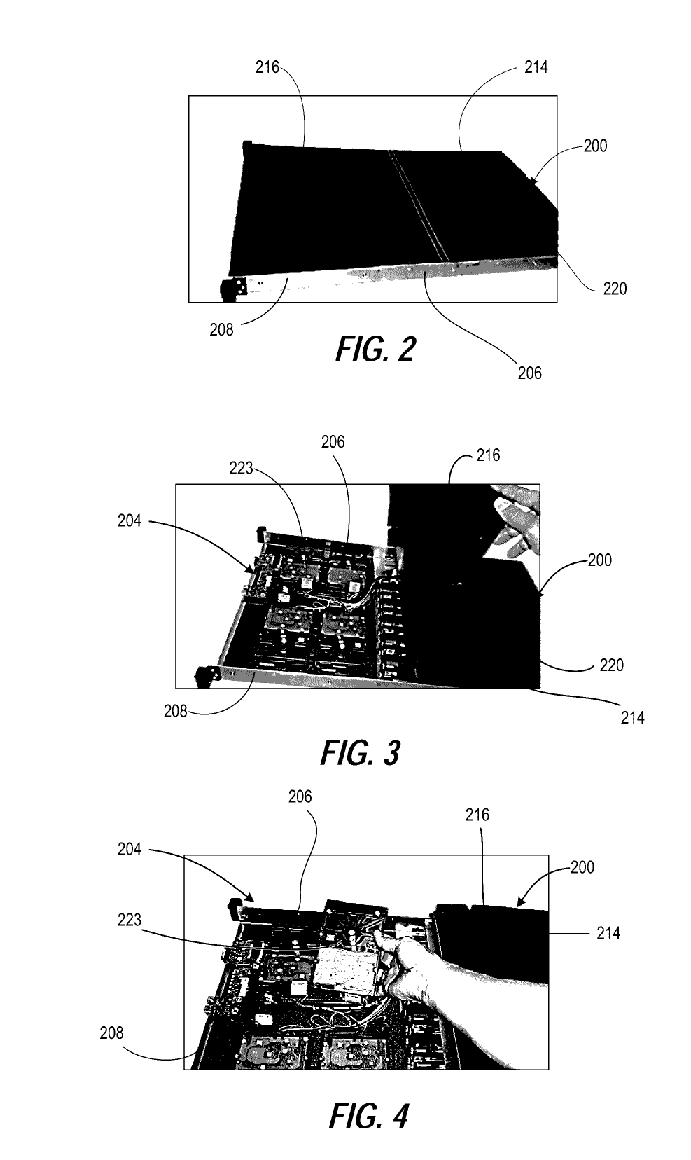

FIGS. 1-2 illustrate an example IHS 100 having functional compute components 104. For purposes of this disclosure, an information handling system, such as IHS 100, may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a handheld device, personal computer, a server, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

Returning to FIG. 1, IHS 100 includes a chassis 106 configured with infrastructure components 107 such as a power supply unit (PSU) 109 and fan modules 113 arranged for housing the compute components 104. In a particular embodiment, the chassis 106 includes a bottom segment 108 having a base wall 110 attached to lateral walls 111 forming a volume in which to receive the compute components 104. Connecting cabling 112 interconnect the compute components 104 to provide a fully functional IHS 100. A cover 114 is fixedly engageable to the bottom segment 108 to enclose inserted IHS components. To facilitate assembly and servicing, the cover 114 includes at least one access panel 116 that can be moved from a closed position to an open position to expose one or more top loaded slots 118 within the chassis 106. A fixedly engageable portion 120 of the cover 114 remains attached to the bottom segment 108. The fixedly engageable portion 120 can present a manual engaging surface 122 to the access panel 116, such as a deformation or friction at adjoining surfaces. The manual engaging surface 122 can enable a tool-less opening by applied manual force. The fixedly engageable portion 120 counters the applied force, remaining attached to the bottom segment 108.

In one or more embodiments, the access panel 116 can be a detachable portion 124 of the cover 114. In one or more embodiments, the access panel 116 can be a horizontally slideable portion 126 to close and open a door aperture 128 formed in the fixedly engageable portion 120. In one or more embodiments, the access panel 116 can be a flip up portion 130 that is hingedly attached to the fixedly engageable portion 120 to open and close the door aperture 128 formed in the fixedly engageable portion 120. The access panel 116 enables insertion and removal of the respective compute component 104 such as storage drives 123, after assembly of the chassis 106.

FIGS. 2-4 illustrate an example planar cover 214 of an IHS 200. The planar cover 214 is formed by molding a flexible material having an access panel 216 hinged to a fixedly engageable portion 220. FIG. 2 illustrates the planar cover 214 in a closed position to a base segment 208 of a chassis 206. FIG. 3 illustrates the access panel 216 in an open position, exposing compute components 204 that include storage drives 223. FIG. 4 illustrates a storage drive 223 removably detached from the base segment 208 of the chassis 206 for servicing and replacement using the access provided by the opened access panel 216.

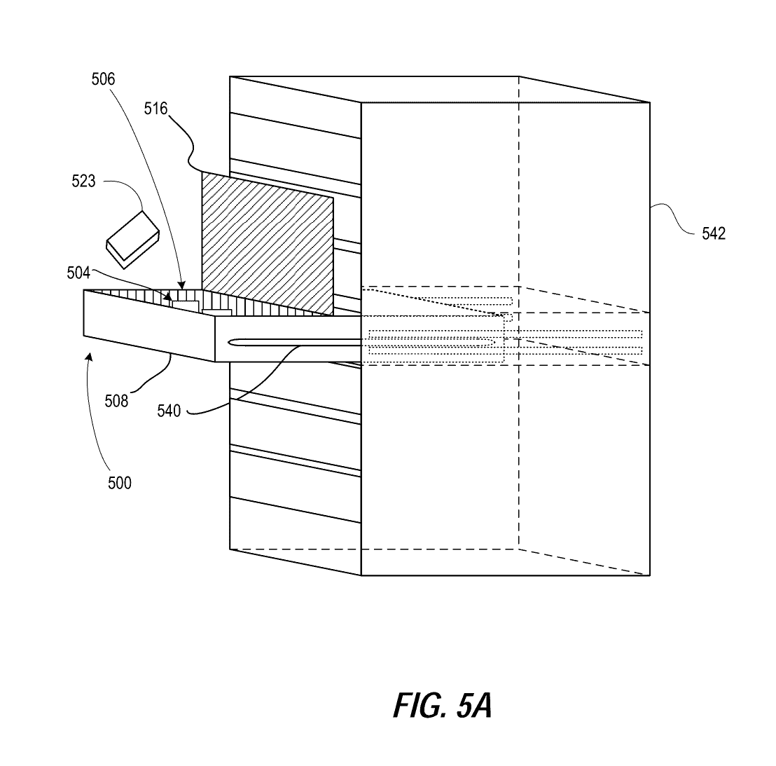

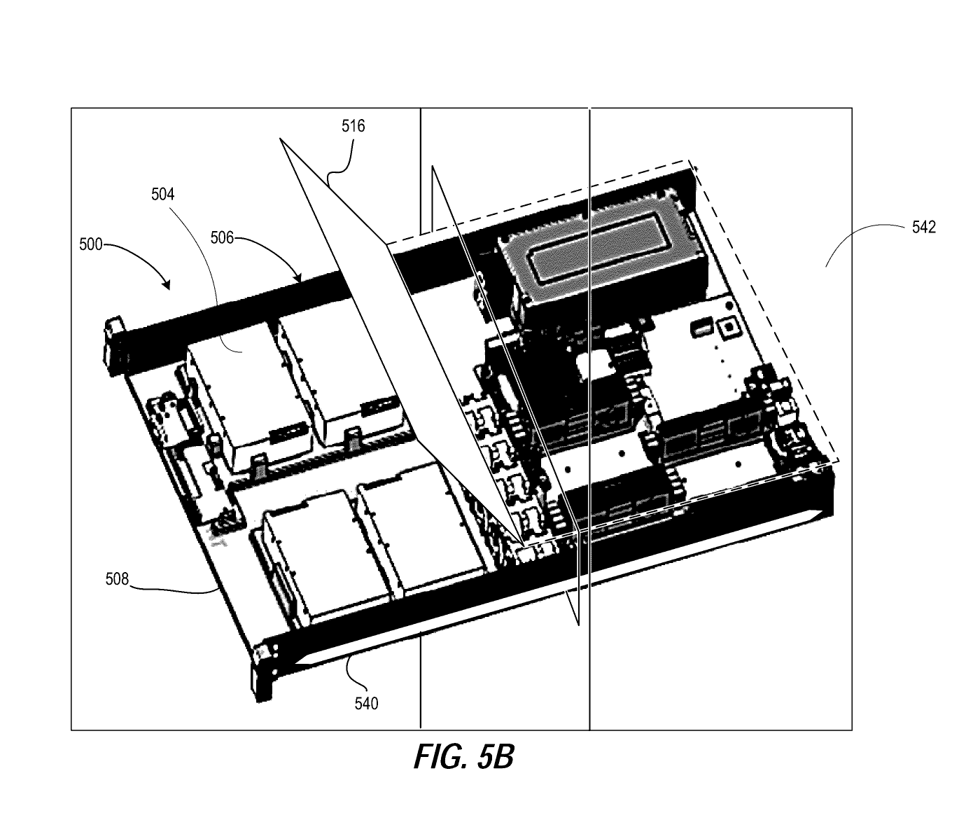

FIGS. 5A-5B illustrate an example IHS 500 having exterior rack mounting guides 540 attached to a bottom segment 508 for insertion of a chassis 506 into an IHS rack 542. The exterior rack mounting guides 540 support the bottom segment 508 in a partially extended state from the IHS rack 542 to allow opening an access panel 516 for servicing or inserting compute components 504 such as a storage drive 523 while the chassis 506 is held in place in the IHS rack 542.

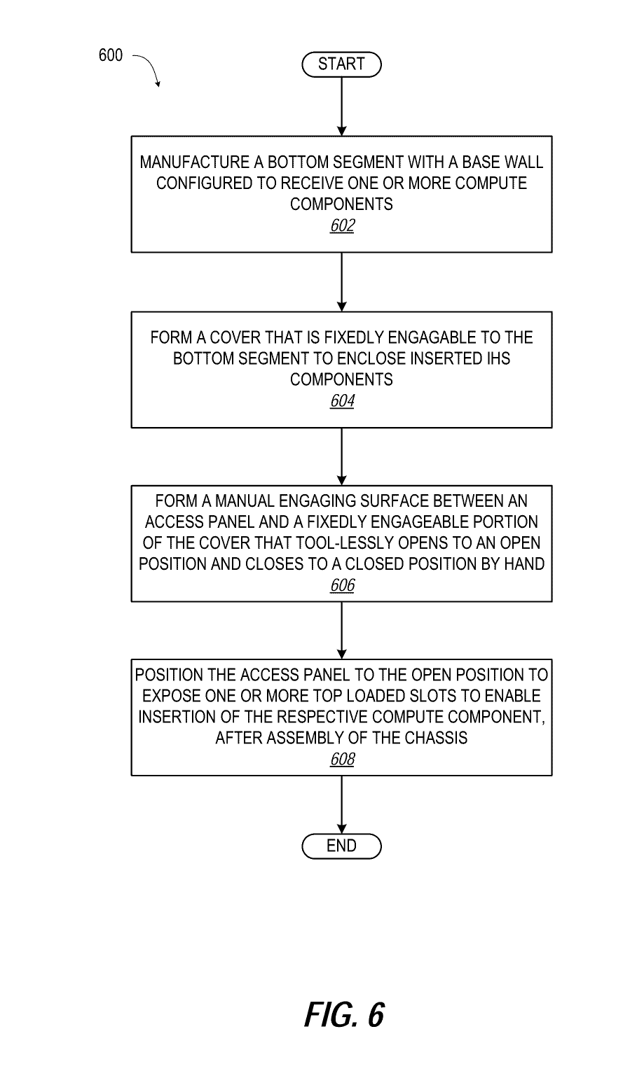

FIG. 6 illustrates a method 600 of manufacturing a chassis of an IHS. In one or more embodiments, the method 600 begins at start block. The method 600 includes manufacturing a bottom segment of the chassis with a base wall configured to receive one or more compute components (block 602). The method 600 includes forming a cover having at least one portion that is fixedly engageable to the bottom segment to enclose inserted IHS components and at least one moveable access panel (block 604). In one embodiment, the cover is molded from flexible material into a planar structure that is engageable to lateral walls of the bottom segment and that has a hinging lateral portion connecting at least one access panel to a fixedly engageable portion.

The method 600 includes forming a manual engaging surface between an access panel and a fixedly engageable portion of the cover that toollessly opens to an open position and closes to a closed position by hand (block 606). The access panel can move with respect to the fixedly engageable portion by hinging, sliding, or detaching. The method 600 can include positioning the access panel to the open position to expose one or more top loaded slots to enable insertion or removal of the respective compute component, after assembly of the chassis (block 608). The method 600 ends.

In the above described flow chart of FIG. 6, one or more of the methods may be embodied in an automated manufacturing system that performs a series of functional processes. In some implementations, certain steps of the methods are combined, performed simultaneously or in a different order, or perhaps omitted, without deviating from the scope of the disclosure. Thus, while the method blocks are described and illustrated in a particular sequence, use of a specific sequence of functional processes represented by the blocks is not meant to imply any limitations on the disclosure. Changes may be made with regards to the sequence of processes without departing from the scope of the present disclosure. Use of a particular sequence is therefore, not to be taken in a limiting sense, and the scope of the present disclosure is defined only by the appended claims.

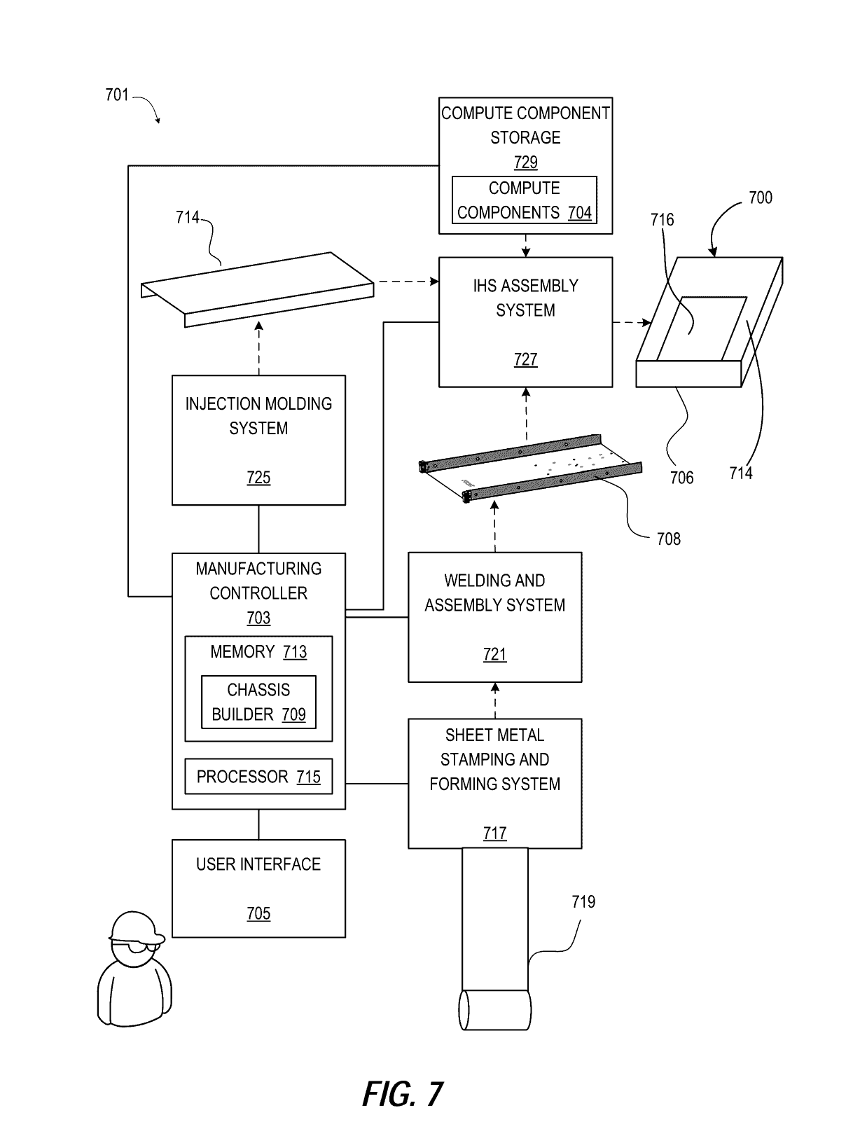

FIG. 7 illustrates a manufacturing system 701 for manufacturing an IHS 700. For clarity, a single manufacturing controller 703 forms an IHS 700 including a chassis 706 that houses compute components 704 that are serviceable via a cover 714, although certain processes can be distributed by location or under separate control. A user interface 705 provides a human interface to the manufacturing controller 703 to initiate execution of a chassis builder 709 contained in memory 713 and executed on a processor 715. The manufacturing controller 703 can direct a sheet metal stamping and forming system 717 to process rolled sheet metal 719 that is completed in a welding and assembly system 721 to form a base segment 708 of the chassis 706. An injection molding system 725 can convert a flexible material into the cover 714, with one or more access panels 716 for servicing. An IHS assembly system 727 can insert compute components 704 selected from compute component storage 729 into the chassis 706 and enclose with the cover 714.

One or more of the embodiments of the disclosure described can be implementable, at least in part, using a software-controlled programmable processing device, such as a microprocessor, digital signal processor or other processing device, data processing apparatus or system. Thus, it is appreciated that a computer program for configuring a programmable device, apparatus or system to implement the foregoing described methods is envisaged as an aspect of the present disclosure. The computer program may be embodied as source code or undergo compilation for implementation on a processing device, apparatus, or system. Suitably, the computer program is stored on a carrier device in machine or device readable form, for example in solid-state memory, magnetic memory such as disk or tape, optically or magneto-optically readable memory such as compact disk or digital versatile disk, flash memory, etc. The processing device, apparatus or system utilizes the program or a part thereof to configure the processing device, apparatus, or system for operation.

While the description of the cover herein provides for the access panel to be physically connected (e.g., connected via the hinging lateral portion) to the fixedly engageable portion, the disclosure also applies to configurations in which the access panel is not actually engaged with or physically attached to the other portion of the cover when in the open state. With these embodiments, the access panel can be an independent, removable piece that can be engaged via its own engagement mechanisms to the chassis and/or the fixed portion of the cover, such that the cover comprises multiple individual portions covering different sections of the chassis.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The description of the present disclosure has been presented for purposes of illustration and description, but is not intended to be exhaustive or limited to the disclosure in the form disclosed. Many modifications and variations will be apparent to those of ordinary skill in the art without departing from the scope of the disclosure. The described embodiments were chosen and described in order to best explain the principles of the disclosure and the practical application, and to enable others of ordinary skill in the art to understand the disclosure for various embodiments with various modifications as are suited to the particular use contemplated.

What is claimed is:

1. A chassis of an information handling system (IHS), the chassis comprising:
a bottom segment having a base wall to receive one or more compute components; and
a cover that has a fixed portion that is fixably engaged to the bottom segment to form a casing enclosing inserted IHS components and that has at least one access panel that can be moved from a closed position to an open position to expose one or more top loaded slots and enable insertion and/or removal of the respective compute component, after assembly of the chassis.

2. The chassis of claim 1, wherein the at least one access panel comprises a detachable portion of the cover and a fixedly engageable portion of the cover to provide support and protection to compute components.

3. The chassis of claim 1, wherein the bottom segment comprises a latching structure that engages the at least one access panel to the fixedly engageable portion to require a tool-less opening by applied manual force, wherein the fixedly engageable portion is engaged to the bottom segment to counter the applied force to remain attached to the bottom segment.

4. The chassis of claim 1, wherein the at least one access panel comprises a horizontally slideable portion to close and open a door aperture formed in the fixedly engaged portion.

5. The chassis of claim 1, wherein the at least one access panel comprises a flip up portion that is hingedly attached to the fixedly engageable portion to open and close a door aperture formed in the fixedly engaged portion.

6. The chassis of claim 1, wherein:
the bottom segment comprises lateral walls attached to the base wall; and
the cover comprises:
a planar structure engageable to the lateral walls; and
a hinging lateral portion connecting the at least one access panel to the fixed engageable portion.

7. The chassis of claim 7, wherein the cover comprises a flexible, molded cover.

8. The chassis of claim 1, further comprising exterior rack mounting guides attached to the bottom segment for insertion of the chassis into an IHS rack and for supporting the bottom segment in a partially extended state from the IHS rack that allows opening of the at least one access panel for servicing or inserting the one or more compute components while the chassis is held in place in the IHS rack.

9. An information handling system (IHS) comprising:
one or more compute components;
a chassis configured with infrastructure components arranged for housing the one or more compute components, the chassis comprising a bottom segment having a base wall to receive the one or more compute components;
one or more connecting cabling interconnecting the compute components to assemble a fully functional IHS; and
a cover that is fixedly engaged to the bottom segment to form a casing enclosing inserted IHS components and that has at least one access panel that can be moved from a closed position to an open position to expose one or more top loaded slots and enable insertion and/or removal of the respective compute component, after assembly of the chassis.

10. The IHS of claim 9, wherein the at least one access panel comprises a detachable portion of the cover and a fixedly engageable portion of the cover to provide support and protection to compute components.

11. The IHS of claim 9, wherein the bottom segment comprises a latching structure that engages the at least one access panel to the fixedly engageable portion to require a tool-less opening by applied manual force, wherein the fixedly engageable portion is engaged to the bottom segment to counter the applied force to remain attached to the bottom segment.

12. The IHS of claim 9, wherein the at least one access panel comprises a horizontally slideable portion to close and open a door aperture formed in the fixedly engaged portion.

13. The IHS of claim 9, wherein the at least one access panel comprises a flip up portion that is hingedly attached to the fixedly engageable portion to open and close a door aperture formed in the fixedly engaged portion.

14. The IHS of claim 9, wherein:
the bottom segment comprises lateral walls attached to the base wall; and
the cover comprises:
a planar structure engageable to the lateral walls; and
a hinging lateral portion connecting the at least one access panel to the fixed engageable portion.

15. The IHS of claim 14, wherein the cover comprises a flexible, molded cover.

16. The IHS of claim 9, further comprising exterior rack mounting guides attached to the bottom segment for insertion of the chassis into an IHS rack and for supporting the bottom segment in a partially extended state from the IHS rack that allows opening of the at least one access panel for servicing or inserting the one or more compute components while the chassis is held in place in the IHS rack.

17. A method of manufacturing a chassis of an information handling system (IHS), the method comprising:
manufacturing a bottom segment with a base wall configured to receive one or more compute components; and
forming a cover that is fixedly engagable to the bottom segment to enclose inserted IHS components and that has at least one access panel that can be moved from a closed position to an open position to expose one or more top loaded slots and enable insertion and/or removal of the respective compute component, after assembly of the chassis.

18. The method of claim 17, wherein forming the cover further comprises forming a manual engaging surface that tool-lessly opens and closes by hand.

19. The method of claim 17, wherein the bottom segment includes lateral walls that are attached to the base wall, and the cover comprises a planar structure that is engageable to the lateral walls and that has a hinging lateral portion connecting the at least one access panel to a fixedly engageable portion.

20. The method of claim 19, further comprising making the cover by molding a flexible material to resiliently attach the at least one access panel to the fixedly engageable portion.
